(19) United States
(12) Patent Application Publication
(10) Pub. No.: US 2025/0327209 A1
(43) Pub. Date: Oct. 23, 2025

(54) SYSTEMS, METHODS, AND VESSELS FOR EPITAXIAL DEPOSITIONS

(71) Applicant: ASM IP Holding B.V., Almere (NL)

(72) Inventors: Gianluca Rengo, Leuven (BE); Rami Khazaka, Leuven (BE)

(21) Appl. No.: 19/182,248

(22) Filed: Apr. 17, 2025

Related U.S. Application Data
(60) Provisional application No. 63/635,965, filed on Apr. 18, 2024.

(51) Int. Cl. C30B 25/16; C30B 25/14

(52) U.S. Cl. CPC C30B 25/165; C30B 25/14

(57) ABSTRACT

Apparatuses, vessels, and methods for forming superlattices are described. Related structures are described as well. In some embodiments, co-flow of one or more precursors and one or more etchants is used to manufacture superlattices comprising pseudomorphic layers, such as Si-SiGe superlattices for CFETS and 3D-DRAM.

### CROSS-REFERENCE TO RELATED APPLICATION(S)

This Application claims the benefit of U.S. Provisional Application 63/635,965 filed on Apr. 18, 2024, the entire contents of which are incorporated herein by reference.

### FIELD OF INVENTION

The present disclosure generally relates to methods for forming silicon-silicon germanium stacks and to related structures. Such structures are useful in the field of integrated circuits, for example in the context of gate-all-around or nanosheet field effect transistors.

### BACKGROUND OF THE DISCLOSURE

Epitaxial SiGe/Si multistacks, i.e. superlattices, with sharp interfaces are required for several applications, like Complementary field effect transistors (CFET) and three-dimensional rapid access memories (3D DRAM). As the thickness of the SiGe layers increases, lattice mismatch between SiGe and Si leads to the buildup of strain energy, which causes the onset of relaxation mechanisms—primarily the formation of misfit dislocations. This occurs when the SiGe layer reaches the so-called critical thickness (hc) that mainly depends on the Ge fraction in SiGe. Dislocations are preferably avoided as they cause degradation in the device performance and impede the control on the interface morphology. Similar issues can occur in epitaxial superlattices of other semiconductor pairs, such as gallium arsenide (GaAs) and aluminum gallium arsenide (AlGaAs).

Thus, it is an object of the present disclosure to provide systems, sub-systems, and methods for forming strained, pseudomorphic superlattices.

### SUMMARY OF THE DISCLOSURE

Described herein is an epitaxial deposition apparatus comprising a reaction chamber that comprises a substrate support that is constructed and arranged for supporting a substrate during an epitaxial deposition process; a precursor module comprising a plurality of precursor sources comprising a plurality of precursors; an etchant module comprising one or more etchant sources comprising one or more etchants; a gas distribution system comprising one or more reaction chamber valves, the gas distribution system is constructed and arranged for forming a first gas mixture and a second gas mixture from the plurality of precursors and the one or more etchants; a sequence controller operably connected to the one or more reaction chamber valves and being programmed to cause the epitaxial deposition apparatus to execute a plurality of deposition cycles, wherein ones from the plurality of cycles comprises sequentially executing a first pulse and a second pulse, wherein the first pulse comprises operating the one or more reaction chamber valves to expose the substrate to the first gas mixture to form a first epitaxial layer on the substrate; wherein the second pulse comprises operating the one or more reaction chamber valves to expose the substrate to the second gas mixture to form a second epitaxial layer on the substrate; wherein the first gas mixture comprises one or more first precursors; wherein the second gas mixture comprises one or more second precursors; wherein the first gas mixture and the second gas mixture comprise an etchant; and, wherein the first gas mixture and the second gas mixture are different; thereby forming a superlattice on the substrate.

In some embodiments, the one or more first precursors comprise a first silicon

precursor.

In some embodiments, the one or more second precursors comprise a second silicon precursor and a germanium precursor.

In some embodiments, the first silicon precursor and the second silicon precursor are the same.

In some embodiments, the etchant comprises a halogen.

In some embodiments, at least one of the first silicon precursor and the second

silicon precursor comprises a silane comprising from at least one to at most 6 silicon atoms.

In some embodiments, the silane comprises a compound that is selected from silane, disilane, trisilane, tetrasilane, pentasilane, and hexasilane.

In some embodiments, the silane comprises disilane.

In some embodiments, the germanium precursor comprises a germane or halogermane that comprises from at least 1 to at most 6 germanium atoms.

In some embodiments, the germane comprises a compound that is selected from germane, digermane, trigermane, tetragermane, pentagermane, and hexagermane, and tetrachlorogermane.

In some embodiments, the halogen is selected from fluorine, chlorine, bromine, and iodine.

In some embodiments, the etchant is selected from HF, HCl, HBr, and HI.

In some embodiments, the etchant is selected from F₂, Cl₂, Br₂, and I₂.

In some embodiments, the epitaxial deposition apparatus further comprises a carrier

gas source, the carrier gas source comprising a carrier gas, wherein the gas distribution system is constructed and arranged for adding the carrier gas to at least one of the first gas mixture and the second gas mixture.

In some embodiments, the carrier gas comprises at least one of N₂ and H₂.

In some embodiments, the carrier gas comprises a noble gas.

In some embodiments, the epitaxial deposition apparatus further comprises a pressure control system that is constructed and arranged for keeping the reaction chamber at a pressure at or below 10 Torr during the plurality of deposition cycles.

In some embodiments, the epitaxial deposition apparatus further comprises a temperature control system that is constructed and arranged for keeping the reaction chamber at a temperature of at least 400° C. to at most 600° C.

Further described is a precursor vessel comprising a precursor, the precursor vessel being comprised in an epitaxial deposition apparatus that comprises a reaction chamber that comprises a substrate support that is constructed and arranged for supporting a process during an epitaxial deposition process; a precursor module comprising a plurality of precursor sources comprising a plurality of precursors, the plurality of precursor sources comprising the precursor vessel; an etchant module comprising one or more etchant sources comprising one or more etchants; a gas distribution system comprising one or more reaction chamber valves, the precursor distribution is constructed and arranged for forming a first gas mixture and a second gas mixture from the plurality of precursors and the one or more etchants; a sequence controller operably connected to the one or more reaction chamber valves and being programmed to cause the epitaxial deposition apparatus to execute a plurality of deposition cycles, wherein ones from the plurality of cycles comprises sequentially executing a first pulse and a second pulse, wherein the first pulse comprises operating the one or more reaction chamber valves to expose the substrate to the first gas mixture to form a first epitaxial layer on the substrate; wherein the second pulse comprises operating the one or more reaction chamber valves to expose the substrate to the second gas mixture to form a second epitaxial layer on the substrate; wherein the first gas mixture comprises one or more first precursors; wherein the second gas mixture comprises one or more second precursors; wherein the first gas mixture and the second gas mixture comprise an etchant; and, wherein the first gas mixture and the second gas mixture are different; thereby forming a superlattice on the substrate.

Further described is a method comprising providing a substrate to a reaction chamber; executing a plurality of cycles, wherein ones from the plurality of cycles comprises sequentially executing a first pulse and a second pulse, wherein the first pulse comprises exposing the substrate to a first gas mixture to form a first epitaxial layer on the substrate, wherein the second pulse comprises exposing the substrate to a second gas mixture to form a second epitaxial layer on the substrate; wherein the first gas mixture comprises one or more first precursors; wherein the second gas mixture comprises one or more second precursors; wherein the first gas mixture and the second gas mixture comprise an etchant; and, wherein the first gas mixture and the second gas mixture are different; thereby forming a superlattice on the substrate.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates an embodiment of an epitaxial deposition apparatus 100.

FIGS. 2 and 3 illustrate embodiments of methods 200, 300 for epitaxial deposition.

FIG. 4 illustrates an embodiment of a structure 400.

FIG. 5 illustrates an embodiment of a method 500 for epitaxial deposition.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

Suitable substrates include monocrystalline semiconductor wafers, such as silicon wafers, germanium wafers, gallium arsenide wafers, silicon carbide wafers, etc. Semiconductor wafers can have any suitable substrate orientation. For example, silicon wafers can have a (001) orientation or a (110) orientation.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

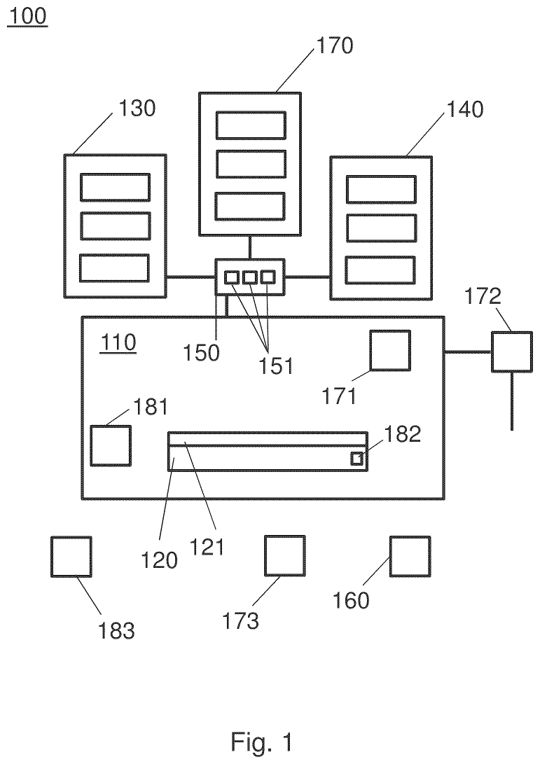

Referring to FIG. 1, described herein is an embodiment of an epitaxial deposition apparatus 100. It comprises a reaction chamber 110. The reaction chamber 110 comprises a substrate support 120. The substrate support 120 is constructed and arranged for supporting a substrate 121 during an epitaxial deposition process. The epitaxial deposition apparatus 100 further comprises a precursor module 130 that comprises plurality of precursor sources. Ones of the precursor sources comprise various precursors.

The epitaxial deposition apparatus 100 further comprises an etchant module 140 that comprises one or more etchant sources. Ones from the etchant sources comprise various etchants.

The epitaxial deposition apparatus 100 further comprises a gas distribution system 150 that comprises one or more chamber valves. The gas distribution system 150 is constructed and arranged for forming a first gas mixture and a second gas mixture from the plurality of precursors and the one or more etchants.

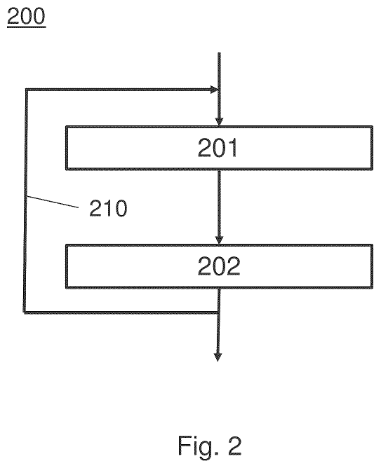

The epitaxial deposition apparatus 100 further comprises a sequence controller 160 that is operably connected to the one or more reaction chamber valves 151 and that is programmed to cause the epitaxial deposition apparatus 100 to execute a cyclical deposition process 200, an embodiment of which is shown in FIG. 2. Such a cyclical deposition process 200 can be advantageously employed for forming a superlattice on the substrate. The cyclical deposition process comprises a plurality of deposition cycles 210. Ones from the plurality of cycles 210 comprise sequentially executing a first pulse 201 and a second pulse 202. It shall be understood that the first pulse 201 and the second pulse 202 can be executed in any order. Thus, in some embodiments the first pulse 201 precedes the second pulse 202. In some embodiments, the second pulse 202 precedes the first pulse 201. The first pulse 201 comprises operating the one or more reaction chamber valves 151 to expose the substrate 121 to the first gas mixture to form a first epitaxial layer on the substrate 121.

The second pulse 202 comprises operating the one or more reaction chamber valves 151 to expose the substrate to the second gas mixture to form a second epitaxial layer on the substrate 121. The first gas mixture comprises one or more first precursors. The second gas mixture comprises one or more second precursors.

In some embodiments, the first gas mixture and the second gas mixture comprise an etchant. In some embodiments, the first gas mixture comprises an etchant and the second gas mixture does not comprise an etchant. In some embodiments, the first gas mixture does not comprise an etchant and the second gas mixture comprises an etchant. The first gas mixture and the second gas mixture are different. Providing an etchant in at least one of the first gas mixture and the second gas mixture can advantageously increase the critical thickness for strain relaxation of heteroepitaxial growth.

Further described herein is an embodiment method. The method can be employed for forming a superlattice on a substrate, such as a superlattice of epitaxial semiconductor layers. Exemplary epitaxial semiconductor layers include indirect bandgap semiconductor pairs such as silicon and silicon-germanium. Other exemplary epitaxial semiconductor layers include direct bandgap semiconductor pairs such as gallium arsenide and aluminum gallium arsenide.

The method employs an epitaxial deposition apparatus according to an embodiment of the present disclosure, such as an epitaxial deposition apparatus 100 described with reference to FIG. 1.

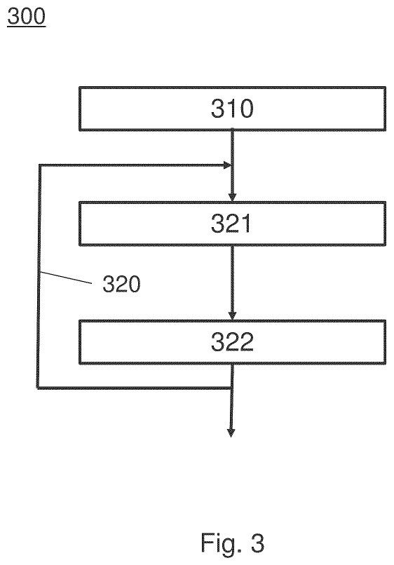

An embodiment of a method 300 as described herein is described with reference to FIG. 3. The method 300 comprises providing 310 a substrate to a reaction chamber. In some embodiments, a method as described herein is executed in a system as described herein. The method 300 further comprises executing a plurality of cycles 320. Ones from the plurality of cycles 320 comprise sequentially executing a first pulse 321 and a second pulse 322. The first pulse 321 comprises exposing the substrate to a first gas mixture to form a first epitaxial layer on the substrate. The second pulse 322 comprises exposing the substrate to a second gas mixture to form a second epitaxial layer on the substrate. It shall be understood that the first and second pulses can be executed in any order; the first pulse 321 can be executed before the second pulse 322, or the second pulse 322 can be executed before the first pulse 321. The first gas mixture comprises one or more first precursors. The second gas mixture comprises one or more second precursors. The first gas mixture and the second gas mixture comprise an etchant. The first gas mixture and the second gas mixture are different, i.e. they have a different composition. For example, the second gas mixture can comprise a precursor that is not comprised in the first gas mixture. Thus, a superlattice is formed on the substrate.

Advantageously, embodiments of the present disclosure can yield excellent epitaxial growth with good surface morphology. Embodiments of the present disclosure can advantageously yield low particle count and low haze.

Advantageously, embodiments of the present disclosure allow pseudomorphically growing Si-SiGe superlattices in which the SiGe layers have a particularly high germanium content. This can in turn make semiconductor device fabrication easier because of enhanced etch contrast between the Si and SiGe layers.

Advantageously, embodiments of the present disclosure can be employed for growing superlattices in which ones from the plurality of first layers and ones of the plurality of second layers, have a different composition. This can be employed by, for example, providing different precursor flows for different layers. For example, embodiments of the present disclosure can be employed for forming multistacks/superlattices with SiGe layers having different germanium contents (example SiGe 15%/Si/SiGe 25%/SiGe 40%). Some embodiments of the present disclosure can be advantageously employed for creating more etch contrasts for sacrificial layers.

In some embodiments, the epitaxial deposition apparatus 100 further comprises a carrier gas source 170. The carrier gas source 170 comprises a carrier gas. In some embodiments, the carrier gas can be selected from H₂, N₂, and a noble gas. Suitable noble gasses include He, Ne, Ar, Kr, and Xe. The gas distribution system 150 is constructed and arranged for adding the carrier gas to at least one of the first gas mixture and the second gas mixture.

In some embodiments, the carrier gas comprises H₂.

In some embodiments, the one or more first precursors comprise a first silicon precursor.

In some embodiments, the one or more second precursors comprise a second silicon precursor and a germanium precursor.

In some embodiments, the first silicon precursor and the second silicon precursor comprise H₂SiCl₂. In some embodiments, the first silicon precursor and the second silicon precursor comprise Si₂H₆. In some embodiments, the germanium precursor comprises GeH₄. In some embodiments, the first silicon precursor comprises Si₂H₆, the second precursor comprises Si₂H₆, and the germanium precursor comprises GeH₄. This can advantageously yield an elevated throughput at a low process temperature.

In some embodiments, the first silicon precursor and the second silicon precursor are the same. In some embodiments, the first silicon precursor and the second silicon precursor are different.

In some embodiments, at least one of the first silicon precursor and the second silicon precursor comprises a silane comprising from at least one to at most 6 silicon atoms.

In some embodiments, the silane comprises a compound that is selected from silane, disilane, trisilane, tetrasilane, pentasilane, and hexasilane. In some embodiments, the silane comprises disilane.

In some embodiments, the first precursor and the second precursor comprise monosilane. In some embodiments, the first precursor and the second precursor comprise disilane. In some embodiments, the first precursor and the second precursor comprise trisilane. In some embodiments, the first precursor and the second precursor comprise tetrasilane. In some embodiments, the first precursor and the second precursor comprise pentasilane. In some embodiments, the first precursor and the second precursor comprise hexasilane.

In some embodiments, tetrasilane can be selected from n-tetrasilane and iso- tetrasilane, In some embodiments, pentasilane can be selected from n-pentasilane, iso-pentasilane, neo-pentasilane, and cyclo-pentasilane. In some embodiments, hexasilane can be selected from n- hexasilane, iso-hexasilane, and cyclo-hexasilane.

In some embodiments, at least one of the first precursor and the second precursor comprise a halosilane such as a fluorosilane, a chlorosilane, a bromosilane, or a iodosilane. For example, at least one of the first precursor and the second precursor can comprise a compound having the general formula SiₙH₂ₙ₊₂₋ₘXₘ, wherein n is an integer from at least 1 to at most 6, wherein m is an integer from at least 1 from at most 2n+2, and wherein X is a halogen such as fluorine, chlorine, bromine, and iodine.

In some embodiments, the first gas mixture comprises a plurality of silicon precursors. For example, the first gas mixture can comprise a silane and a halosilane. For example, the first gas mixture can comprise two different halosilanes. For example, the first gas mixture can comprise two different chlorosilanes. For example, the first gas mixture can comprise Si₂Cl₆ and Si₂Cl₅H.

In some embodiments, the second gas mixture comprises a plurality of silicon precursors and one or more germanium precursors. For example, the second gas mixture can comprise a silane, a halosilane, and a germane. For example, the second gas mixture can comprise two different halosilanes and a germane. For example, the second gas mixture can comprise two different chlorosilanes and germane. For example, the first gas mixture can comprise Si₂Cl₆, Si₂Cl₅H, and GeH₄.

In some embodiments, the etchant comprises a halogen.

In some embodiments, the halogen is selected from fluorine, chlorine, bromine, and iodine.

In some embodiments, the etchant is selected from HF, HCl, HBr, and HI.

In some embodiments, the etchant is selected from F₂, Cl₂, Br₂, and I₂.

In some embodiments, the germanium precursor comprises a germane that comprises from at least 1 to at most 6 germanium atoms.

In some embodiments, the germane comprises a compound that is selected from germane, digermane, trigermane, tetragermane, pentagermane, and hexagermane. In some embodiments, the germane comprises digermane.

In some embodiments, the germanium precursor monogermane. In some embodiments, the germanium precursor comprises digermane. In some embodiments, the germanium precursor comprises trigermane. In some embodiments, the germanium precursor comprises tetragermane. In some embodiments, the germanium precursor comprises pentagermane. In some embodiments, the germanium precursor comprises hexagermane.

In some embodiments, tetragermane can be selected from n-tetragermane and iso- tetragermane, In some embodiments, pentagermane can be selected from n-pentagermane, iso- pentagermane, neo-pentagermane, and cyclo-pentagermane. In some embodiments, hexagermane can be selected from n-hexagermane, iso-hexagermane, and cyclo-hexagermane.

In some embodiments, the germanium precursor comprises a halogermane such as a fluorogermane, a chlorogermane, a bromogermane, or a iodogermane. For example, the germanium precursor can comprise a compound having the general formula GeₙH₂ₙ₊₂₋ₘXₘ, wherein n is an integer from at least 1 to at most 6, wherein m is an integer from at least 1 from at most 2n+2, and wherein X is a halogen such as fluorine, chlorine, bromine, and iodine. In some embodiments, the germanium precursor comprises GeCl₄.

In some embodiments, the first pulse and the second pulse are separated by a purge. In other words, the first pulse can be separated from a subsequent second pulse by a first purge, and the second pulse can be separated from a subsequent first pulse by means of a second purge. The purge, e.g. the first purge and/or the second purge, can comprise providing a purge gas mixture to the reaction chamber. Suitable purge gas mixtures can comprise one or more of N₂, H₂, and a noble gas such as He, Ne, Ar, Kr, and Xe.

In some embodiments, the purge gas mixture comprises one or more precursors and an etchant. For example, the purge gas mixture can comprise a silane, a halosilane, and a hydrogen halide. For example, the silane can comprise disilane. For example, the halosilane can comprise a chlorosilane such as dichlorosilane. For example, the hydrogen halide can comprise HCl. For example, the purge gas mixture can comprise disilane, dichlorosilane, and HCl.

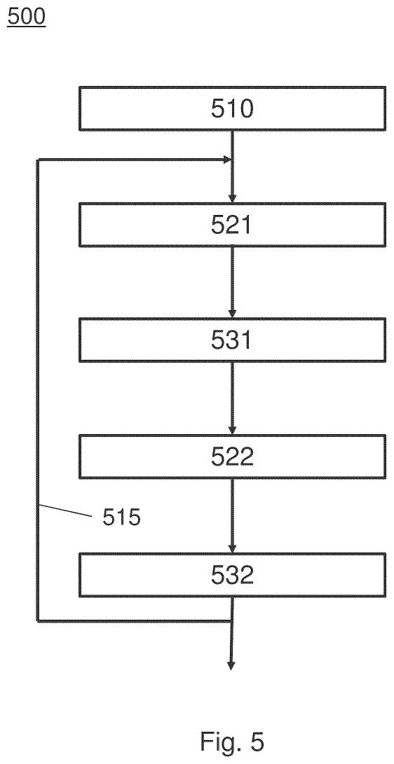

An exemplary embodiment of a process 500 comprising purges is described referring to FIG. 5. The process 500 comprises providing 510 a substrate to a reaction chamber.

Then, the process 500 comprises executing a plurality of deposition cycles 515. Ones from the plurality of deposition cycles 515 comprise a first pulse 521 as described herein and a second pulse 522 as described herein. Ones from the plurality of deposition cycles 515 further comprise a first purge 531 between a first pulse 521 and a subsequent second pulse 522, and a second purge 532 between a second pulse 522 and a subsequent first pulse 521. The first purge 531 can comprise contacting the substrate with a first purge gas. The second purge 532 can comprise contacting the substrate with a second purge gas. In some embodiments, the first purge gas and the second purge gas have the same composition. In some embodiments, the first purge gas and the second purge gas have a different composition. In some embodiments, at least one of the purge gas and the second purge gas have a composition as described herein. For example, at least one of the can comprise one or more precursors and an etchant.

In some embodiments, an epitaxial deposition apparatus 100 according to an embodiment of the present disclosure comprises one or more of a pressure control system and a temperature control system.

The pressure control system can be constructed and arranged for keeping the reaction chamber at a reaction chamber pressure. In some embodiments, the reaction chamber pressure is maintained at or below 10 Torr during the plurality of deposition cycles. In some embodiments, the reaction chamber pressure is maintained at a pressure of at least 1 Torr to at most 10 Torr, or at a pressure of at least 2 Torr to at most 5 Torr, or at a pressure of about 3 Torr. In some embodiments, the pressure control system comprises a pressure sensor 171 comprised in the reaction chamber 110, a vacuum pump 172 that is in fluid connection with the reaction chamber 110 and a pressure processor 173. The pressure sensor 171 can measure a reaction chamber pressure. The pressure processor 173 can generate a vacuum pump control signal based on the reaction chamber pressure. The vacuum pump 172 can have a variable pumping speed that can be regulated by the vacuum pump control signal. Suitable pressure processors include proportional- integral-derivative (PID) controllers, general-purpose integrated circuits, and application-specific integrated circuits (ASICs).

The temperature control system can be constructed and arranged for keeping the reaction chamber 110 at a temperature of at least 400° C. to at most 600° C., or at a temperature of at most 200° C., or at a temperature of at least 200° C. to at most 400° C., or at a temperature of at least 300° C. to at most 500° C., or at a temperature of at least 400° C. to at most 600° C., for example at a temperature of about 530° C. Advantageously, reducing the deposition temperature can be effective in delaying nucleation and propagation of misfit dislocations due to kinetic barriers. Thus, pseudomorphic superlattices can be grown more easily at lower temperatures and the thickness prior to the occurrence of relaxation can be extended even beyond the critical thickness if lower deposition temperatures are used.

In some embodiments, the temperature control system comprises a temperature sensor 181 comprised in the reaction chamber 110, a substrate heater 182, and a temperature processor 183. The temperature sensor 181 can generate a temperature-indicative signal based on a measured temperature, e.g. a measured substrate temperature. The temperature processor 183 can generate a substrate heater control signal based on the temperature-indicative signal. The substrate heater 182 can have a variable heat dissipation rate that can be regulated by the substrate heater control signal. Suitable temperature processors 183 include proportional-integral-derivative (PID) controllers, general-purpose integrated circuits, and application-specific integrated circuits (ASICs).

Further described herein is a precursor vessel that comprises a precursor. The precursor vessel is comprised in an epitaxial deposition apparatus as described herein.

In an exemplary embodiment of a method as described herein, the first and second silicon precursor comprise disilane (Si₂H₆), the germanium precursor comprises germane (GeH₄ ), the substrate is maintained at a temperature of 530° C. during deposition, the reaction chamber is maintained at a pressure of 3 Torr during deposition, and a superlattice of silicon and silicon- germanium layers is formed on a 300 mm (100) p-type monocrystalline silicon wafer, in which the silicon-germanium layers comprise 37 atomic percent germanium and 63 atomic percent silicon. Germane is provided to the reaction chamber diluted to 5 volume percent in a H₂ carrier gas stream. When a silicon-germanium (SiGe) layer is grown on (100) p-type monocrystalline silicon, pseudomorphic epitaxial growth, in absence of strain relaxation, was observed up to a layer thickness of 80 nm, indicating a critical thickness of over 80 nm.

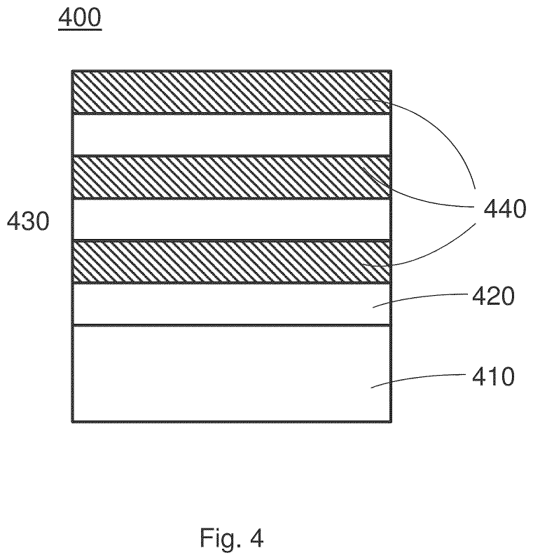

FIG. 4 illustrates an embodiment of a structure 400 that can be formed by means of methods and apparatuses according to embodiments of the present disclosure. The structure 400 comprises a monocrystalline substrate 410 and a buffer layer 420 which is epitaxially grown on the substrate 410. The buffer layer 420 has a composition which is substantially identical to the composition of the substrate 410. On top of the buffer layer, a Si-SiGe superlattice is grown that consists of a plurality of SiGe layers 440 and Si layers 430. SiGe stands for an alloy of silicon (Si) and germanium (Ge).

1. An epitaxial deposition apparatus comprising
a reaction chamber that comprises a substrate support that is constructed and arranged for supporting a substrate during an epitaxial deposition process;
a precursor module comprising a plurality of precursor sources comprising a plurality of precursors;
an etchant module comprising one or more etchant sources comprising one or more etchants;
a gas distribution system comprising one or more reaction chamber valves, the gas distribution system is constructed and arranged for forming a first gas mixture and a second gas mixture from the plurality of precursors and the one or more etchants; and
a sequence controller operably connected to the one or more reaction chamber valves and being programmed to cause the epitaxial deposition apparatus to execute a plurality of deposition cycles to form a superlattice on the substrate, wherein ones from the plurality of deposition cycles comprises sequentially executing a first pulse and a second pulse,
wherein the first pulse comprises operating the one or more reaction chamber valves to expose the substrate to the first gas mixture to form a first epitaxial layer on the substrate;
wherein the second pulse comprises operating the one or more reaction chamber valves to expose the substrate to the second gas mixture to form a second epitaxial layer on the substrate;
wherein the first gas mixture comprises one or more first precursors;
wherein the second gas mixture comprises one or more second precursors;
wherein the first gas mixture and the second gas mixture comprise an etchant; and
wherein the first gas mixture and the second gas mixture are different.

2. The epitaxial deposition apparatus according to claim 1, wherein the one or more first precursors comprise a first silicon precursor.

3. The epitaxial deposition apparatus according to claim 2, wherein the one or more second precursors comprise a second silicon precursor and a germanium precursor.

4. The epitaxial deposition apparatus according to claim 3, wherein the first silicon precursor and the second silicon precursor are the same.

5. The epitaxial deposition apparatus according to claim 1, wherein the etchant comprises a halogen.

6. The epitaxial deposition apparatus according to claim 3, wherein at least one of the first silicon precursor and the second silicon precursor comprises a silane comprising from at least one to at most 6 silicon atoms.

7. The epitaxial deposition apparatus according to claim 6, wherein the silane comprises a compound that is selected from silane, disilane, trisilane, tetrasilane, pentasilane, and hexasilane.

8. The epitaxial deposition apparatus according to claim 7, wherein the silane comprises disilane.

9. The epitaxial deposition apparatus according to claim 3, wherein the germanium precursor comprises a germane or halogermane that comprises from at least 1 to at most 6 germanium atoms.

10. The epitaxial deposition apparatus according to claim 9, wherein the germane comprises a compound that is selected from germane, digermane, trigermane, tetragermane, pentagermane, and hexagermane, and tetrachlorogermane.

11. The epitaxial deposition apparatus according to claim 5, wherein the halogen is selected from fluorine, chlorine, bromine, and iodine.

12. The epitaxial deposition apparatus according to claim 1, wherein the etchant is selected from HF, HCl, HBr, and HI.

13. The epitaxial deposition apparatus according to claim 1, wherein the etchant is selected from F₂, Cl₂, Br₂, and I₂.

14. The epitaxial deposition apparatus according to claim 1, further comprising a carrier gas source, the carrier gas source comprising a carrier gas, wherein the gas distribution system is constructed and arranged for adding the carrier gas to at least one of the first gas mixture and the second gas mixture.

15. The epitaxial deposition apparatus according to claim 14, wherein the carrier gas comprises at least one of N₂and H₂.

16. The epitaxial deposition apparatus according to claim 14, wherein the carrier gas comprises a noble gas.

17. The epitaxial deposition apparatus according to claim 1, further comprising a pressure control system that is constructed and arranged for keeping the reaction chamber at a pressure at or below 10 Torr during the plurality of deposition cycles.

18. The epitaxial deposition apparatus according to claim 1, further comprising a temperature control system that is constructed and arranged for keeping the reaction chamber at a temperature of at least 400° C. to at most 600° C.

19. A precursor vessel comprising a precursor, the precursor vessel being comprised in an epitaxial deposition apparatus that comprises a reaction chamber that comprises a substrate support that is constructed and arranged for supporting a substrate during an epitaxial deposition process;
a precursor module comprising a plurality of precursor sources comprising a plurality of precursors, the plurality of precursor sources comprising the precursor vessel;
an etchant module comprising one or more etchant sources comprising one or more etchants;
a gas distribution system comprising one or more reaction chamber valves, the gas distribution system being constructed and arranged for forming a first gas mixture and a second gas mixture from the plurality of precursors and the one or more etchants; and
a sequence controller operably connected to the one or more reaction chamber valves and being programmed to cause the epitaxial deposition apparatus to execute a plurality of deposition cycles to form a superlattice on the substrate, wherein ones from the plurality of deposition cycles comprises sequentially executing a first pulse and a second pulse,
wherein the first pulse comprises operating the one or more reaction chamber valves to expose the substrate to the first gas mixture to form a first epitaxial layer on the substrate;
wherein the second pulse comprises operating the one or more reaction chamber valves to expose the substrate to the second gas mixture to form a second epitaxial layer on the substrate;
wherein the first gas mixture comprises one or more first precursors;
wherein the second gas mixture comprises one or more second precursors;
wherein the first gas mixture and the second gas mixture comprise an etchant; and
wherein the first gas mixture and the second gas mixture are different.

20. A method comprising providing a substrate to a reaction chamber; and
executing a plurality of cycles to form a super lattice on the substrate, wherein ones from the plurality of cycles comprises sequentially executing a first pulse and a second pulse,
wherein the first pulse comprises exposing the substrate to a first gas mixture to form a first epitaxial layer on the substrate,
wherein the second pulse comprises exposing the substrate to a second gas mixture to form a second epitaxial layer on the substrate;
wherein the first gas mixture comprises one or more first precursors;
wherein the second gas mixture comprises one or more second precursors;
wherein the first gas mixture and the second gas mixture comprise an etchant; and
wherein the first gas mixture and the second gas mixture are different.
